(19) United States
(12) Patent Application Publication
(10) Pub. No.: US 2025/0226345 A1
(43) Pub. Date: Jul. 10, 2025

(54) Semiconductor Device and Method of Stacking and Interconnecting Semiconductor Assemblies Using Conductive Layer with Graphene Core Shells

(71) Applicant: STATS ChipPAC Pte. Ltd., Singapore (SG)

(72) Inventors: YongMoo SHIN, Incheon (KR); HeeSoo LEE, Incheon (KR); HyunSeok PARK, Gyeonggi-do (KR); EunSu AN, Incheon (KR); Kyungman CHOI, Gyeonggi-do (KR)

(73) Assignee: STATS ChipPAC Pte. Ltd., Singapore (SG)

(21) Appl. No.: 18/405,484

(22) Filed: Jan. 5, 2024

(51) Int. Cl. H01L 23/00; H01L 21/56; H01L 25/065

(52) U.S. Cl. CPC H01L 24/20; H01L 21/565; H01L 24/19; H01L 24/24; H01L 24/82; H01L 25/0652; H01L 24/76; H01L 2224/19; H01L 2224/214; H01L 2224/215; H01L 2224/24137; H01L 2224/24226; H01L 2224/76155; H01L 2224/82102; H01L 2224/82203; H01L 2924/182

(57) ABSTRACT

A semiconductor device has a plurality of stacked semiconductor assemblies. Each semiconductor assembly has a first electrical component, and an electrical connector disposed adjacent to the first electrical component. A conductive layer with a graphene core shell is formed between the first electrical component and electrical connector. The graphene core shell has a copper core or silver core. The conductive layer has a plurality of cores covered by graphene and the graphene is interconnected within the conductive layer to form an electrical path. The conductive layer has a thermoset material or polymer or composite epoxy type matrix. A second electrical component is disposed adjacent to a side of the electrical connector opposite the first electrical component. An encapsulant is deposited around the first electrical component, second electrical component, and electrical connector. The conductive layer is formed between the second electrical component and electrical connector over the encapsulant.

### FIELD OF THE INVENTION

The present invention relates in general to semiconductor devices and, more particularly, to a semiconductor device and method of stacking and interconnecting semiconductor assemblies using an electrical connector and conductive layer with graphene core shells.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a system in package (SiP) module for higher density in a small space and extended electrical functionality. Within the SIP module, semiconductor die and IPDs are disposed on a substrate for structural support and electrical connection through a vertical and horizontal interconnect structure. An encapsulant is deposited over the semiconductor die, IPDs, and substrate.

The SIP modules can be stacked for greater device integration and functionality. The stacked modules need to be interconnected. A common interconnect structure uses multiple conductive layers sintered by heat. However, thermal sintering is time consuming and reduces manufacturing productivity and device throughput.

### BRIEF DESCRIPTION OF THE DRAWINGS

FIGS. 1a-1c illustrate a semiconductor wafer with a plurality of semiconductor die separated by a saw street;

FIGS. 2a-2n illustrate a process of stacking and interconnecting semiconductor assemblies using an electrical connector and conductive layer with graphene core shells;

FIGS. 3a-3b illustrate further detail of the graphene core shell within the conductive layer;

FIGS. 4a-4c illustrate a process of forming a graphene core shell;

FIGS. 5a-5c illustrate further detail of stacking and interconnecting semiconductor assemblies using an electrical connector and conductive layer with graphene core shells;

FIGS. 6a-6f illustrate another process of stacking and interconnecting semiconductor assemblies using an electrical connector and conductive layer with graphene core shells;

FIG. 7 illustrates stacking and interconnecting semiconductor assemblies from FIGS. 5a-5c with semiconductor packages from FIGS. 2a-2n;

FIGS. 8a-8b illustrate further detail of stacking and interconnecting semiconductor assemblies from FIG. 7 with an interconnect substrate;

FIGS. 9a-9b illustrate using EHD jet printing to deposit the conductive material over the encapsulant;

FIG. 10 illustrates using aerosol jet printing to deposit the conductive material over the encapsulant; and

FIG. 11 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

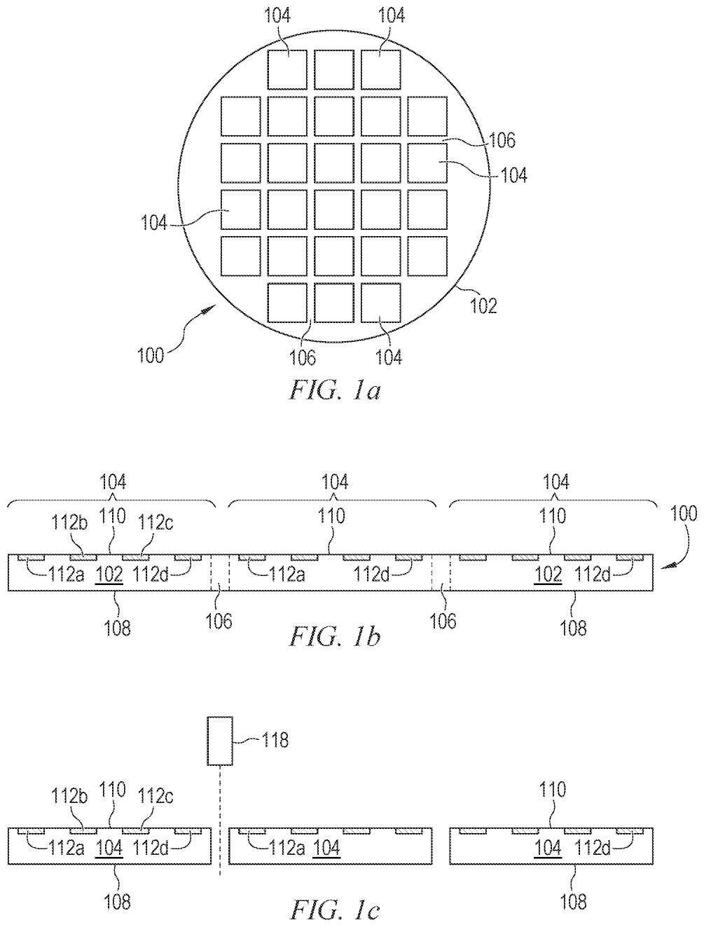

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm). Alternatively, wafer 100 can be a mold surface, organic or inorganic substrate, or target substrate suitable for graphene transfer.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. In one embodiment, semiconductor die 104 can be memory or memory controller. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), Cu, tin (Sn), nickel (Ni), gold (Au), silver (Ag), or other suitable electrically conductive material. Conductive layer 112 operates as contact pads electrically connected to the circuits on active surface 110. In one embodiment, each semiconductor die 104 has conductive layers 112a, 112b, 112c, and 112d.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

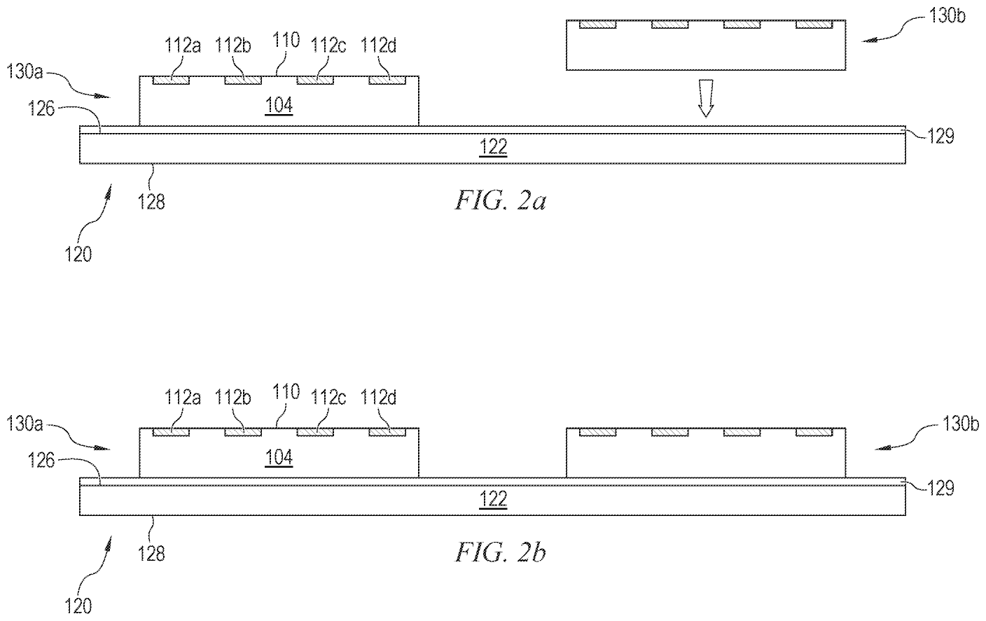

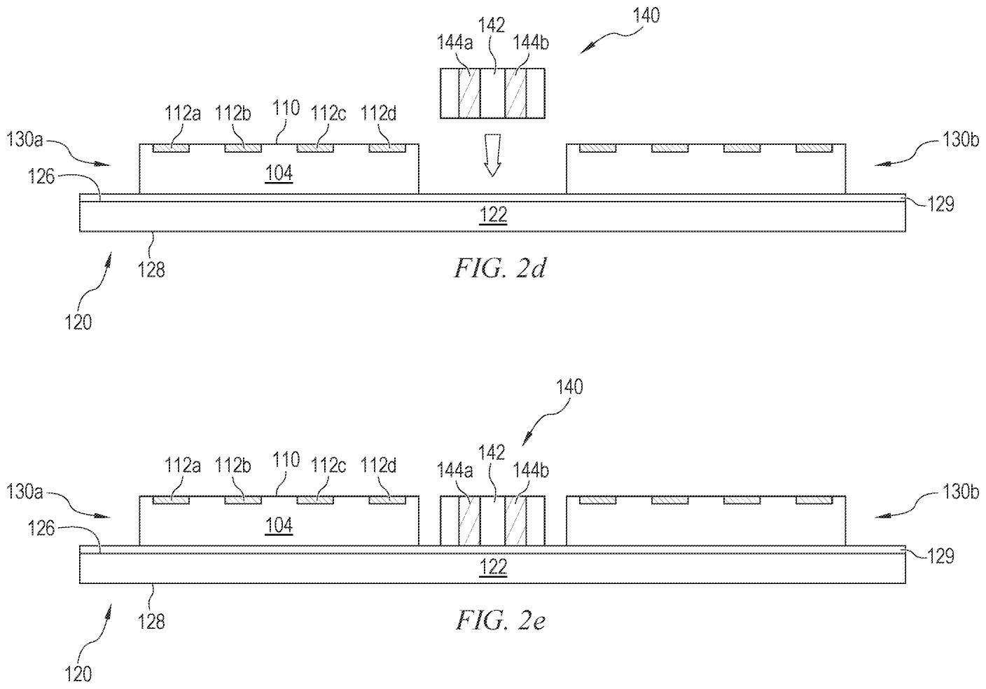

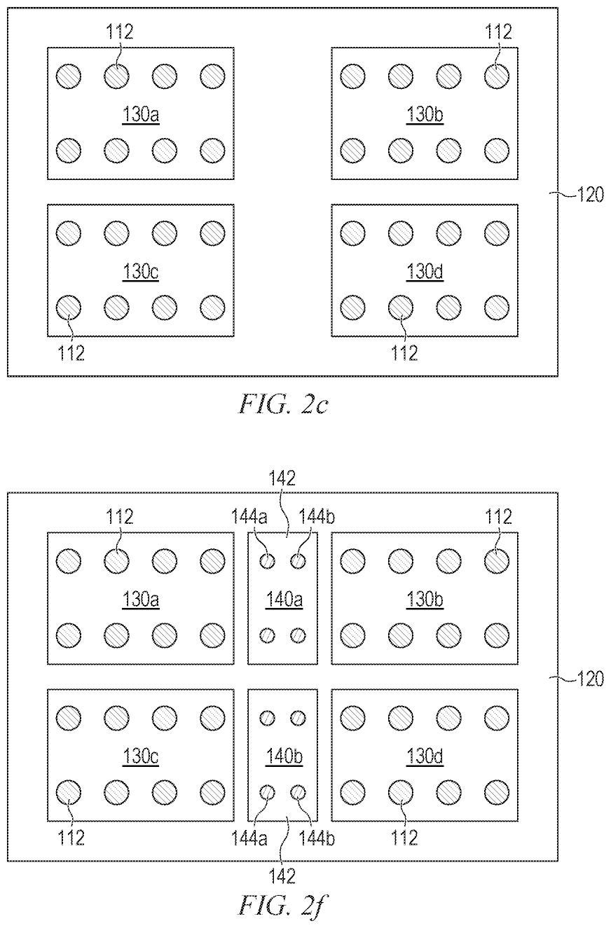

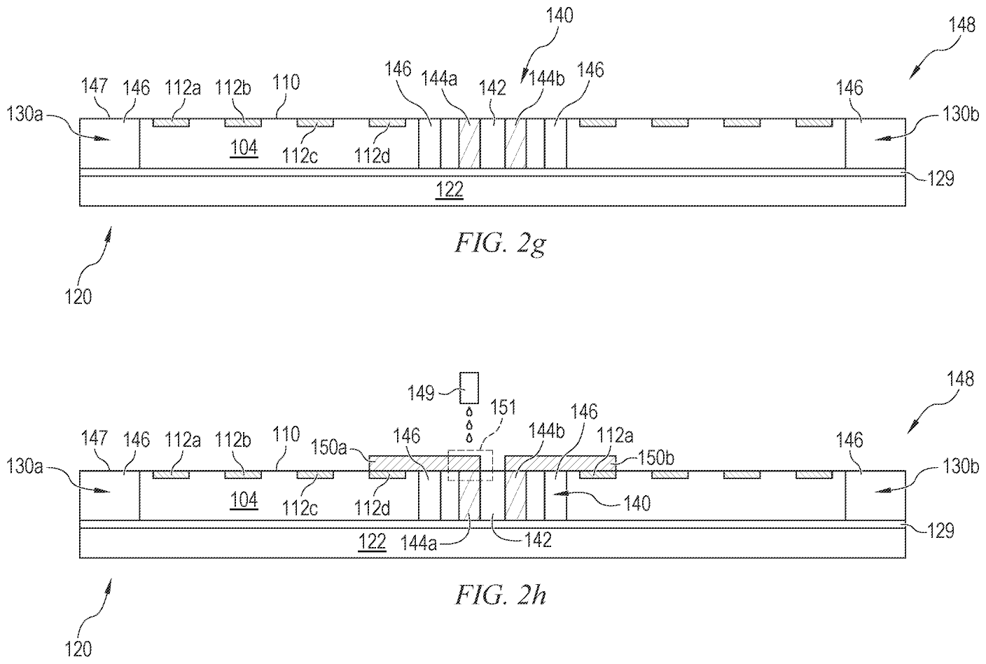

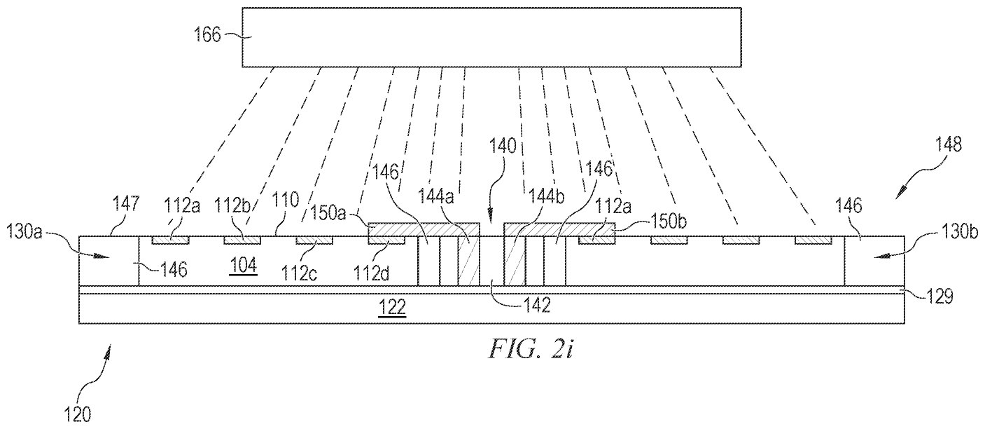

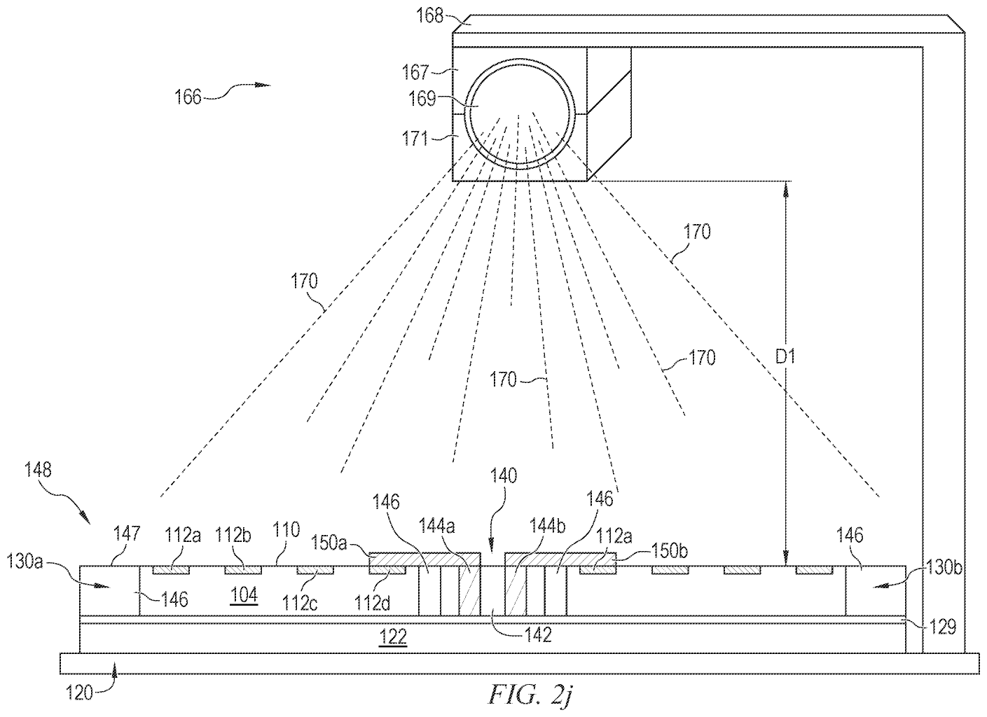

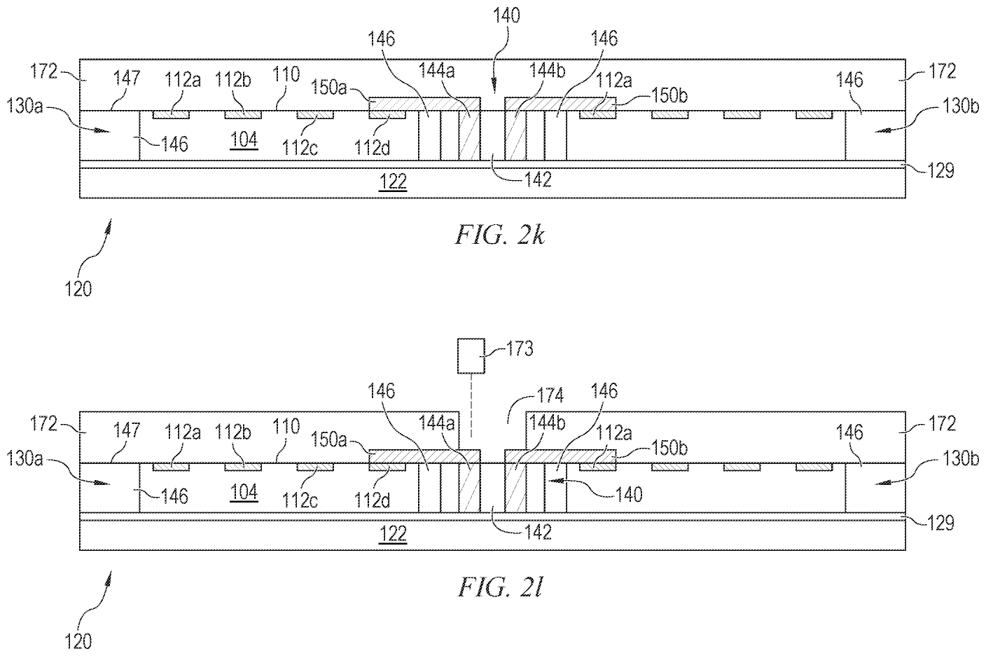

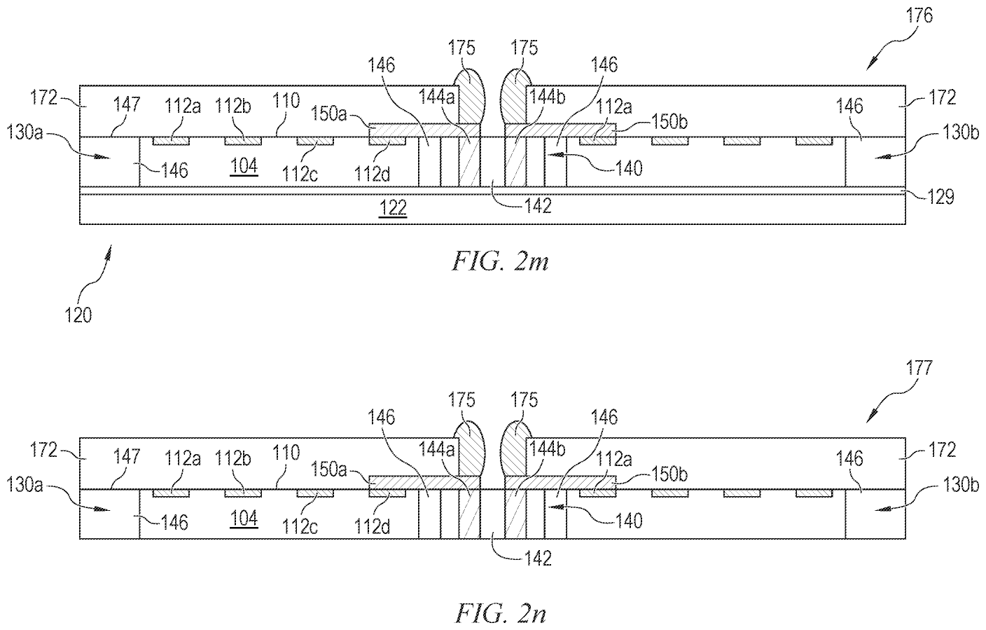

FIGS. 2a-2n illustrate a process of stacking and interconnecting semiconductor assemblies using an electrical connector and conductive layer with graphene core shells. FIG. 2a illustrates a temporary substrate or wafer 120 containing sacrificial material 122, such as silicon, polymer, beryllium oxide, glass, or other suitable low-cost, rigid material for structural support. In one embodiment, temporary substrate 120 is a carrier tape. Alternatively, substrate 120 can be silicon, germanium, aluminum phosphide, aluminum arsenide, gallium arsenide, gallium nitride, indium phosphide, silicon carbide, or other bulk material for structural support. Substrate 120 has major surface 126 and major surface 128, opposite surface 126. A temporary bonding layer 129 is formed over surface 126 of substrate 120. Temporary bonding layer 129 can be a sacrificial or etch-stop layer made of aluminum arsenic (AlAs), aluminum gallium arsenic (AlGaAs), indium gallium phosphorus (InGaP), or aluminum indium phosphorus (AlInP).

In FIG. 2b, electrical components 130a-130b are disposed over surface 126 of substrate 120. Electrical components 130a-130b can be similar to, or made similar to, semiconductor die 104 from FIG. 1c with conductive layer 112 oriented away from surface 126 of substrate 120. Alternatively, electrical components 130a-130b can include other semiconductor die, semiconductor packages, surface mount devices, RF components, discrete electrical devices, or integrated passive devices (IPD).

Electrical components 130a-130b are positioned over substrate 120 using a pick and place operation. Electrical components 130a-130b are brought into contact with and secured in place by bonding layer 129. FIG. 2b illustrates electrical components 130a-130b bonded to substrate 120. FIG. 2c is a top view of electrical components 130a-130d bonded to substrate 120. Electrical components 130c and 130d can be similar to electrical components 130a and 130b.

In FIG. 2d, electrical connector 140 is disposed over surface 126 of substrate 120. Electrical connector 140 includes base insulating material 142 and electrical conductive vias 144 extending through the base insulating material. Electrical connector 140 is positioned over substrate 120 between electrical components 130a and 130b using a pick and place operation. Electrical connector 140 is brought into contact with and secured in place by bonding layer 129 adjacent to electrical components 130a-130b. FIG. 2e illustrates electrical connector 140 bonded to substrate 120 between and adjacent to electrical components 130a and 130b. FIG. 2f is a top view of electrical connector 140a and 140b bonded to substrate 120 between electrical components 130a and 130b and between electrical components 130c and 130d, respectively. Electrical connector 140b can be similar to electrical connector 140a, collectively referred to as electrical connector 140.

In FIG. 2g, encapsulant or molding compound 146 is deposited over and around electrical components 130a-130d, electrical connector 140, and substrate 120 using a paste printing, compressive molding, transfer molding, liquid encapsulant molding, vacuum lamination, spin coating, or other suitable applicator. Encapsulant 146 can be liquid or granular polymer composite material, such as epoxy resin with filler, epoxy acrylate with filler, or polymer with proper filler. Encapsulant 146 is non-conductive, provides structural support, and environmentally protects the semiconductor device from external elements and contaminants. The combination of electrical components 130a-130d, electrical connectors 140a-140b, encapsulant 146, and substrate 120 constitute semiconductor assembly 148.

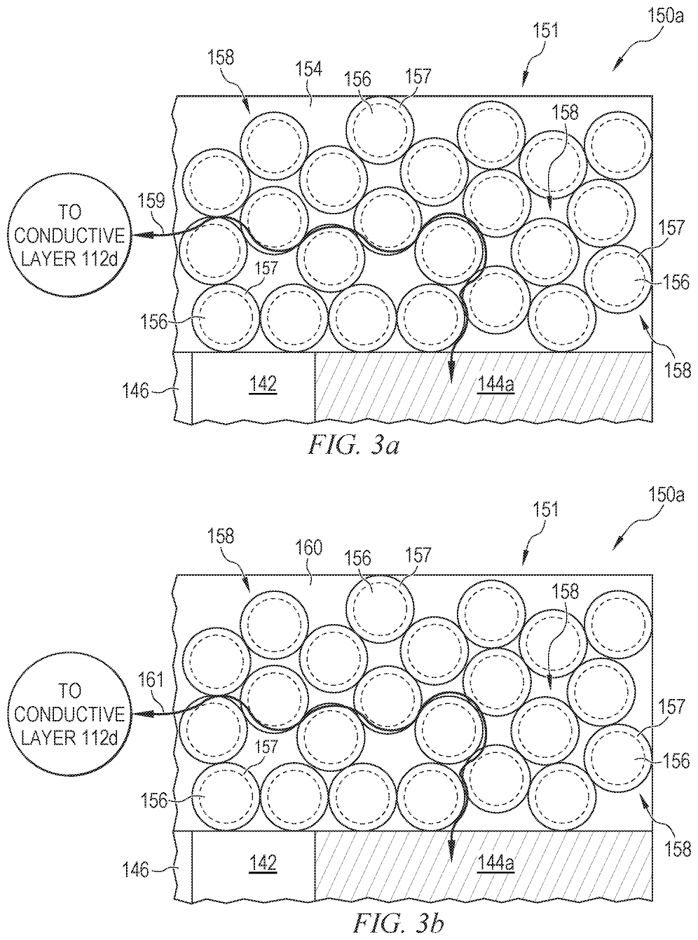

In FIG. 2h, electrically conductive layer or material 150 is deposited, printed, or otherwise formed on surface 147 of encapsulant 146 and active surface 110 of electrical components 130a-130b, including over conductive layer 112, to provide a horizontal electrical interconnect structure across, over, or through the encapsulant between electrical components 130a-130d and electrical connector 140a-140b. Conductive layer 150 is electrically connected between conductive layer 112 of electrical component 130 and conductive vias 144 in electrical connector 140. More specifically, conductive layer 150a is electrically connected between conductive layer 112d of electrical component 130a and conductive via 144a in electrical connector 140a. Conductive layer 150b is electrically connected between conductive layer 112a of electrical component 130b and conductive via 144b in electrical connector 140a. In one embodiment, conductive layers or material 150a-150b, collectively referred to as conductive layer 150, are printed or dispensed onto surfaces 110 and 147 by printer or dispenser 149. Further detail of forming conductive layer 150 is described in FIGS. 3a-3b, 4a-4c, 9a-9b, and 10. Conductive layer 150 can be one or more layers of a matrix, such as thermal set material or polymer, with graphene covered core shells embedded within the matrix. Alternatively, electrically layer 150 is deposited onto surfaces 110 and 147 using evaporation, electrolytic plating, electroless plating, ball drop, screen printing process, injector, or electrohydrodynamic (EHD) jet printing to provide a horizontal electrical interconnect structure across encapsulant 146 between electrical components 130a-130d and electrical connectors 140a-140b. Conductive layer 150 can be one or more layers of Al, Cu, Sn, Ni, Au, Ag, or other suitable electrically conductive material.

FIG. 3a show further detail of region or box 151 from FIG. 2h. Conductive layer or material 150a is disposed over conductive via 144a and base insulating material 142 of electrical connector 140a and surface 147 of encapsulant 146. In one embodiment, conductive layer or material 150a includes matrix 154 and a plurality of cores 156 with graphene coating 157, designated as graphene core shells 158 embedded within the matrix. Matrix 154 can be a thermoset material, such epoxy resin or adhesive with filler containing alumina, Al, aluminum zinc oxide, or other material having good heat transfer and electrically conductive properties. Matrix 154 can be thermal grease such as silicon or polymer type such as polymethyl methacrylate (PMMA) or polyethylene terephthalate (PET). In one embodiment, core 156 is Ag, Cu, Ni, phase change material (PCM), or other suitable metal or similar material. Cores 156 are arranged within matrix 154 so that most if not all graphene coatings 157 covering the core contact at least one adjacent graphene coating to form a continuous and connecting electrical conduction path 159 of graphene coatings through conductive material 150a. A first graphene coating 157 contacts a second adjacent graphene coating, which in turn contacts a third adjacent graphene coating, and so on, to form continuous and connecting electrical conduction path 159 between conductive via 144a and conductive layer 112d. Cores 156 have sufficient density that most if not all the graphene coatings around the cores contact at least one graphene coating around an adjacent core, and typically contact graphene coating of multiple adjacent cores.

In another embodiment, matrix 154 is a polymer or composite epoxy with dispersed graphene, carbon nanotubes, conductive polymers, and the like. For example, matrix 154 can be an Ag ink epoxy for conductive layer or material 150a.

FIG. 3b shows another embodiment of region or box 151 from FIG. 2h. In this case, matrix 160 is solder containing one or more elements of Sn, lead (Pb), or indium (In). Components having a similar function are assigned the same reference number. Again, core 156 can be Cu, Ni, PCM, or other suitable metal or similar material. Each core 156, as embedded in matrix 160, is surrounded or covered by graphene coating or shell 157. In one embodiment, a graphene paste or ink is formed around a Cu or Ag core, designated as graphene core shell 158.

Cores 156 are arranged within matrix 160 so that most if not all graphene coatings 157 covering the core contact at least one adjacent graphene coating to form a continuous and connecting electrical conduction path 161 of graphene coatings through conductive layer or material 150a. Graphene coating 157 of each core 156 contacts the graphene coating of an adjacent core. A first graphene coating 157 contacts a second adjacent graphene coating, which in turn contacts a third adjacent graphene coating, and so on, to form continuous and connecting electrical conduction path 161. Cores 156 have sufficient density that most if not all the graphene coatings around the cores contact at least one graphene coating around an adjacent core, and typically contact graphene coating of multiple adjacent cores.

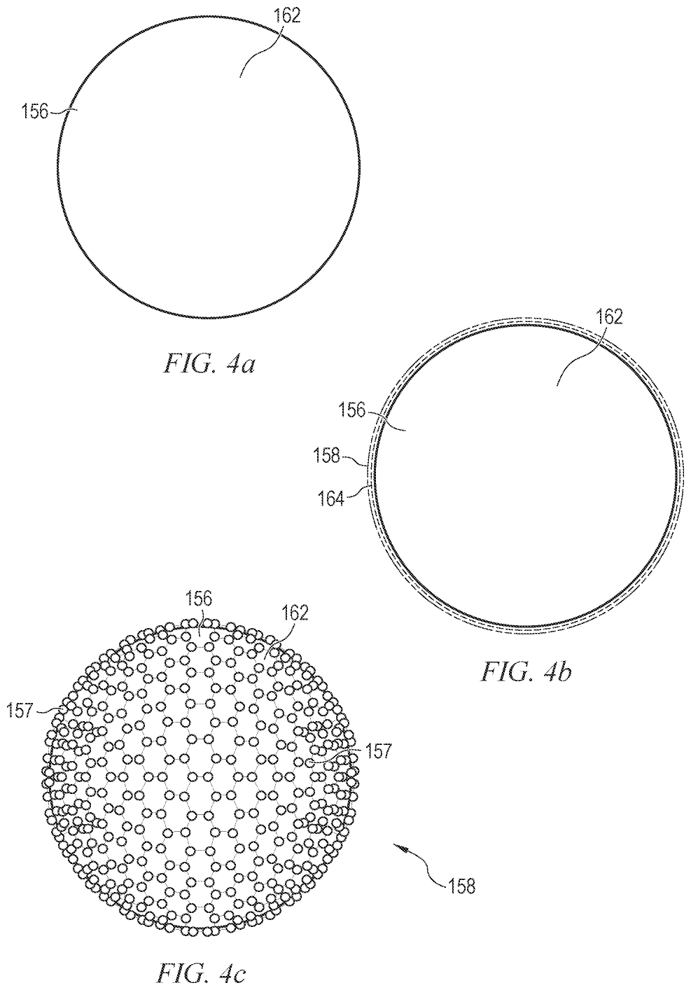

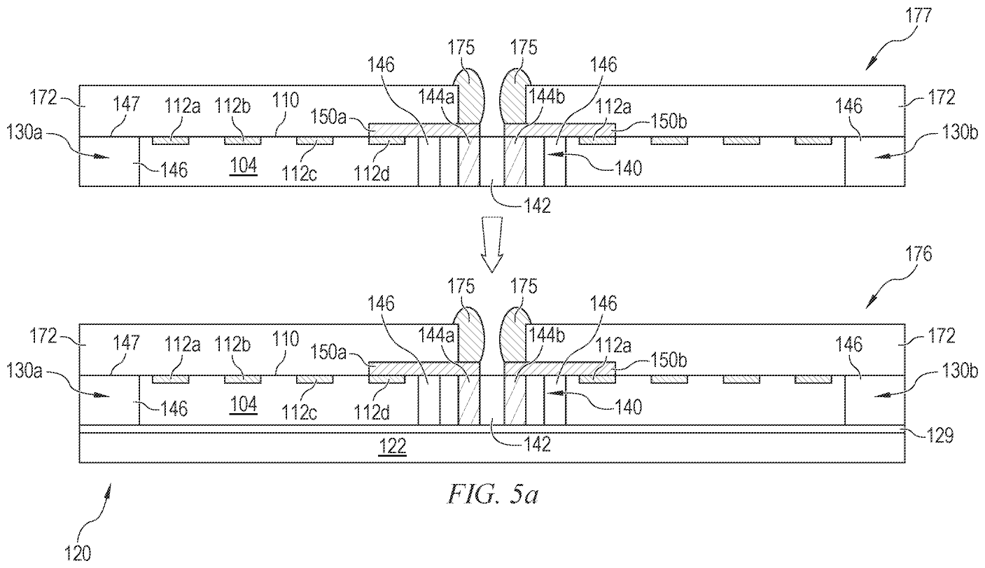

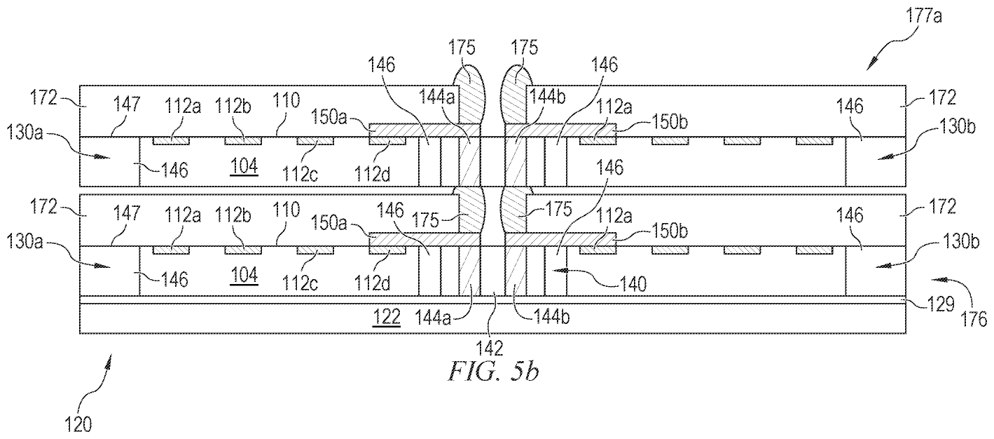

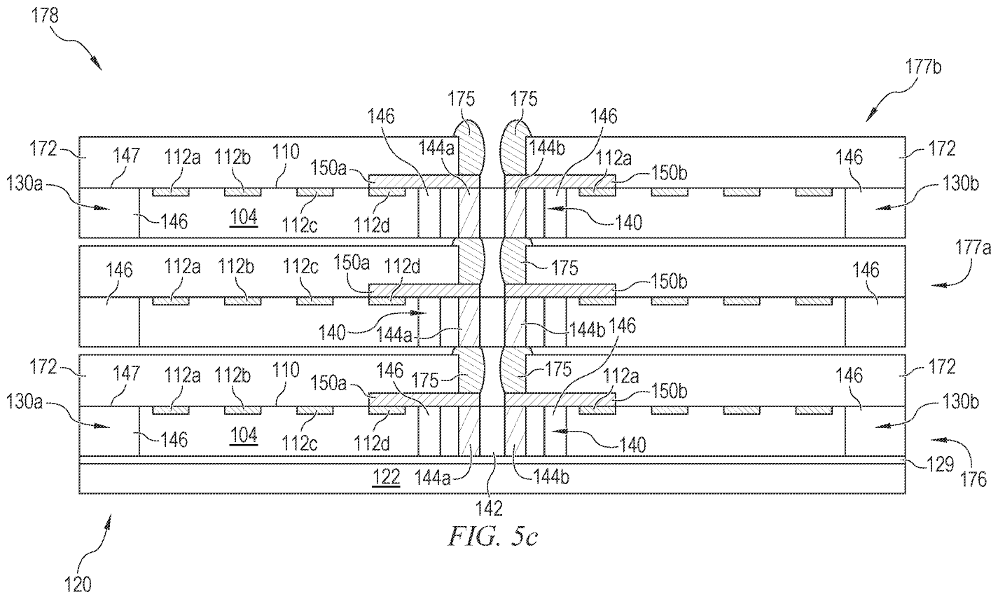

FIGS. 4a-4c illustrate further detail of core 156, graphene coating 157, and graphene core shell 158. In one embodiment, core 156 is Cu, Ni, PCM, or other suitable metal or similar material. FIG. 4b illustrates graphene coating 157 formed over and around surface 162 of core 156. FIG. 4c illustrates further detail of graphene coating 157 formed as a mesh network around surface 162 of core 156, collectively graphene core shell 158. Graphene coating 157 is an allotrope of carbon with one or more layers of carbon atoms each arranged in a two-dimensional (2D) honeycomb lattice. Graphene coating 157 can be formed by CVD. Core 156 is placed in a chamber heated to 900-1080° C. A gas mixture of CH₄/H₂/Ar is introduced into the chamber to initiate a CVD reaction. The carbon source decomposes in the high-temperature reaction chamber as the CVD reaction separates the carbon atoms from the hydrogen atoms, leaving graphene coating 157 on surface 162 of core 156. The release of carbon atoms over core 156 forms a continuous sheet of graphene coating 157. Additional information related to forming graphene coating by CVD is disclosed in U.S. Pat. No. 8,535,553, and hereby incorporated by reference.

Core 156 is PCM capable of phase change from solid to liquid phase or from liquid phase to solid phase within the operating temperature range of the semiconductor chip, e.g., 20-200° C. A first coating 164 is formed around PCM core 156, as shown in FIG. 4b and discussed in published Korean application KR101465616B1. The first coating 164 can be a polymer intermediate layer. A second coating 157 is formed over the first coating 164. Matrix 154 and 160 with graphene covered cores is further disclosed in U.S. Pat. No. 10,421,123, and all are incorporated herein by reference.

The properties of graphene are summarized in Table 1, as follows:

TABLE 1
Properties of graphene

| Parameter | |
|---|---|
| Electronic mobility | 2 × 10⁵ cm² V⁻¹ s⁻¹ |
| Current density | 10⁹ A cm⁻¹ |
| Velocity of fermion (electron) | 10⁶ m s⁻¹ |
| Thermal conductivity | 4000-5000 W m⁻¹ K⁻¹ |
| Tensile strength | 1.5 Tpa |
| Breaking strength | 42 N m⁻¹ |
| Transparency | 97.7% |
| Elastic limit | 20% |
| Surface area | 2360 m² g⁻¹ |

Graphene coating 157 has 100 times the electrical conductivity of Cu. Graphene coating 157 enables epoxy to exhibit electrical conductivity similar to Ag, while reducing or eliminating oxidation. Core shell 158 with Cu or Ag and graphene epoxy is low cost, as compared to sputtering. Graphene coating 157 has a low moisture permeability and a high thermal conductivity of 4000-5000 W m⁻¹ K⁻¹, 10 times higher than Cu at room temperature. Since carbon also has a good solderability and wettability of solder paste. Graphene coating 157 exhibits a high degree of flexibility and remains stable against warpage. Conductive material 150a with graphene Cu or Ag shells 158 improves electrical conductivity, while lowering manufacturing cost. Conductive layer or material 150b follows a similar formation and functionality.

Returning to FIG. 2i, conductive layer 150a-150b undergoes an intensive pulsed light (IPL) irradiation process using radiation source 166 to anneal the conductive layer. FIG. 2j shows further detail of radiation source 166 and the IPL irradiation process. Semiconductor assembly 148 with conductive layer 150a-150b is placed under radiation source 166. Reflector 167 is supported by stand 168. Xenon lamp 169 transmits pulsed light 170 through ultraviolet (UV) filter 171 onto conductive layer 150a-150b. The distance D1 from radiation source 166 to conductive layer 150a-150b is about 14.0 mm. Radiation source 166 pulses light for several milliseconds and can be applied to large area substrate 120 to anneal conductive layer 150.

In FIG. 2k, insulating layer 172 is formed over semiconductor assembly 148 and conductive layer 150. Insulating layer 172 contains one or more layers of silicon dioxide (SiO₂), silicon nitride (Si₃N₄), silicon oxynitride (SiON), tantalum pentoxide (Ta₂O₅), aluminum oxide (Al₂O₃), solder resist, polyimide, benzocyclobutene (BCB), polybenzoxazoles (PBO), and other material having similar insulating and structural properties. Insulating layer 172 can be formed using PVD, CVD, printing, lamination, spin coating, spray coating, sintering or thermal oxidation.

In FIG. 2l, a portion of insulating layer 172 is removed using an etching process or laser direct ablation (LDA) with laser 173 to form opening 174 extending to and exposing conductive layers or material 150a and 150b.

In FIG. 2m, an electrically conductive bump material is deposited into opening 174 over conductive layers 150a and 150b using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 150 using a suitable attachment or bonding process. In one embodiment, the bump material is reflowed by heating the material above its melting point to form balls or bumps 175. In one embodiment, bump 175 is formed over an under bump metallization (UBM) having a wetting layer, barrier layer, and adhesive layer. Bump 175 can also be compression bonded or thermocompression bonded to conductive layer 150. In one embodiment, bump 175 is a copper core bump for durability and maintaining its height. Bump 175 represents one type of interconnect structure that can be formed over conductive layer 150. The interconnect structure can also use bond wires, conductive paste, stud bump, micro bump, or other electrical interconnect. The combination of semiconductor assembly 148, conductive layer 150, insulating layer 172, and bumps 175 constitute semiconductor assembly 176.

In FIG. 2n, substrate 120 and bonding layer 129 are removed from semiconductor assembly 176 by chemical mechanical polishing (CMP), mechanical peel-off, mechanical grinding, thermal bake, UV light, or wet stripping, leaving semiconductor assembly 177.

In FIG. 5a, semiconductor assembly 177a is disposed over semiconductor assembly 176. Semiconductor assembly 177a is mounted to semiconductor assembly 176 with bumps 175 on semiconductor assembly 176 contacting conductive vias 144a and 144b of electrical connector 140 on semiconductor assembly 177a. FIG. 5b shows semiconductor assembly 177a mounted to semiconductor assembly 176. In particular, the electrical signal conduction path from conductive layer 112d on electrical component 130a in semiconductor assembly 176 is routed through conductive layer 150a in semiconductor assembly 176, bump 175 in semiconductor assembly 176, conductive via 144a of electrical connector 140 in semiconductor assembly 177a, and conductive layer 150a in semiconductor assembly 177a to conductive layer 112d in electrical components 130a in semiconductor assembly 177a. The electrical signal conduction path from conductive layer 112a on electrical component 130b in semiconductor assembly 176 is routed through conductive layer 150b in semiconductor assembly 176, bump 175 in semiconductor assembly 176, conductive via 144b of electrical connector 140 in semiconductor assembly 177a, and conductive layer 150b in semiconductor assembly 177a to conductive layer 112a in electrical components 130b in semiconductor assembly 177a.

In FIG. 5c, semiconductor assembly 177b is disposed over and mounted to semiconductor assembly 177a, in a similar manner as FIGS. 5a-5b. Semiconductor assembly 177b is mounted to semiconductor assembly 177a with bumps 175 on semiconductor assembly 177a contacting conductive vias 144a and 144b of electrical connector 140 on semiconductor assembly 177b. The electrical signal conduction path from conductive layer 112d on electrical component 130a in semiconductor assembly 177a is routed through conductive layer 150a in semiconductor assembly 177a, bump 175 in semiconductor assembly 177a, conductive via 144a of electrical connector 140 in semiconductor assembly 177b, and conductive layer 150a in semiconductor assembly 177b to conductive layer 112d in electrical components 130a in semiconductor assembly 177b. The electrical signal conduction path from conductive layer 112a on electrical component 130b in semiconductor assembly 177a is routed through conductive layer 150b in semiconductor assembly 177a, bump 175 in semiconductor assembly 177a, conductive via 144b of electrical connector 140 in semiconductor assembly 177b, and conductive layer 150b in semiconductor assembly 177b to conductive layer 112a in electrical components 130b in semiconductor assembly 177b.

The combination of semiconductor assemblies 176, 177a, and 177b constitute SiP or semiconductor package 178 capable of electrical communication between electrical components 130a-130b in each of the semiconductor assemblies 176, 177a, 177b through electrical connectors 140, bumps 175, and conductive layer or material 150 including graphene core shells for improved conductivity with low resistivity and high thermal conductivity. SiP 178, including electrical connector 140 and conductive layer 150, provides higher density of semiconductor die in a smaller space with extended electrical functionality. In particular, conductive layer 150 with graphene core shells improves signal transmission and reduces propagation delay. The IPL irradiation performs an anneal in less time than a thermal sintering.

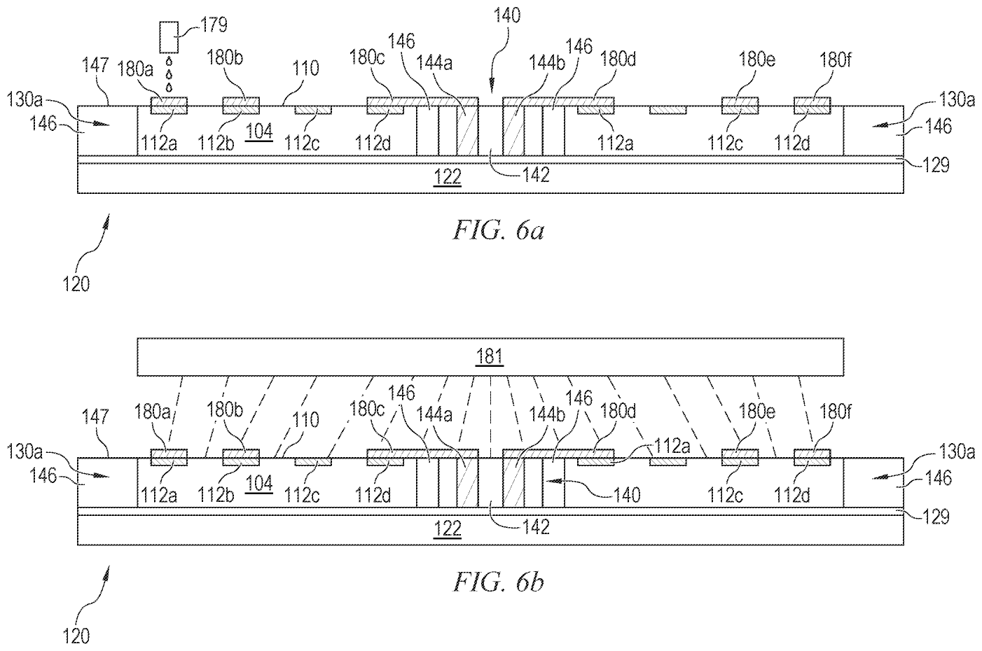

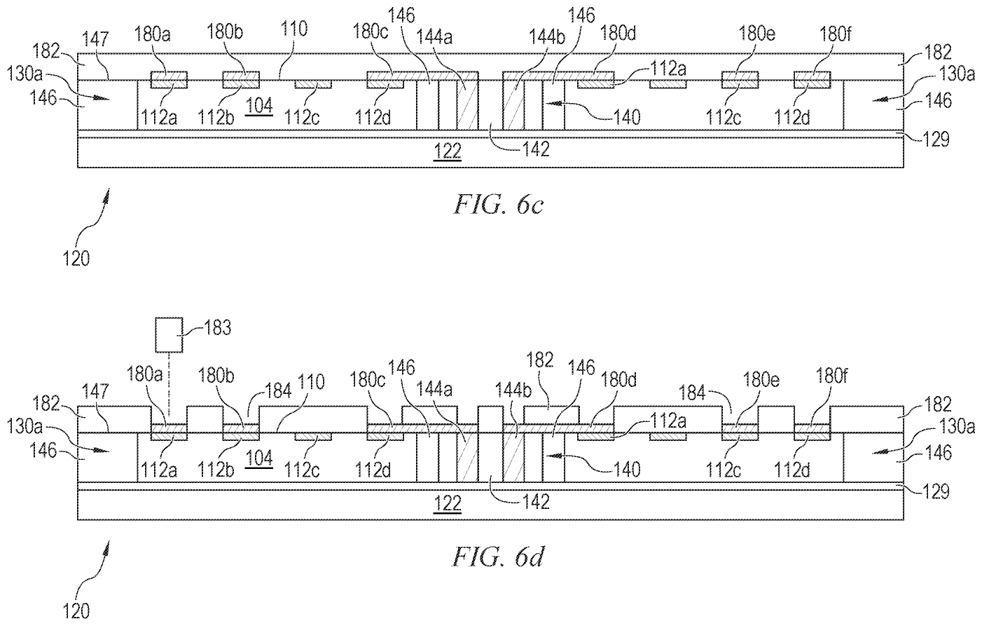

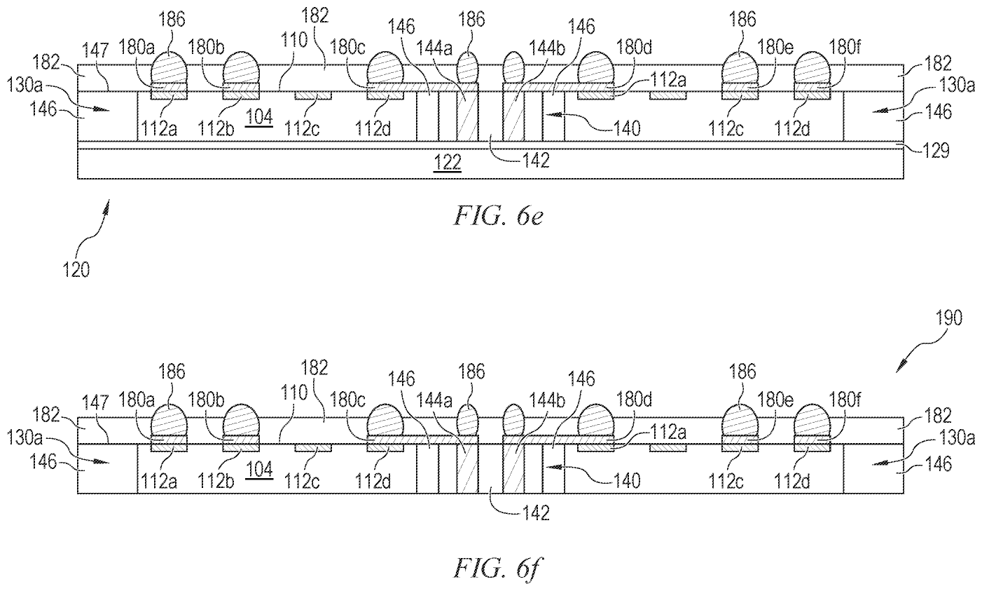

In another embodiment, continuing from FIG. 2g, electrically conductive layer or material 180 is deposited, printed, or otherwise formed on surface 147 of encapsulant 146 and active surface 110 of electrical components 130a-130b, including conductive layer 112, as shown in FIG. 6a. Conductive layer or material 180 provides a horizontal electrical interconnect structure across, over, or through the encapsulant between electrical components 130a-130d and electrical connector 140a-140b. Components having a similar function are assigned the same reference number. Conductive layer 180 is electrically connected to conductive layer 112 of electrical component 130. More specifically, conductive layer 180a is electrically connected to conductive layer 112a of electrical component 130a and conductive layer 180b is electrically connected to conductive layer 112b of electrical component 130a.

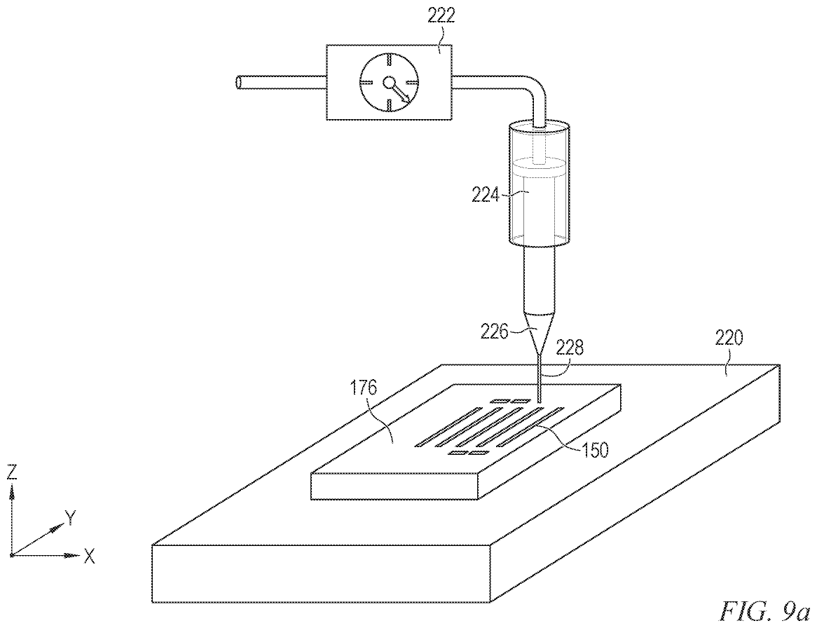

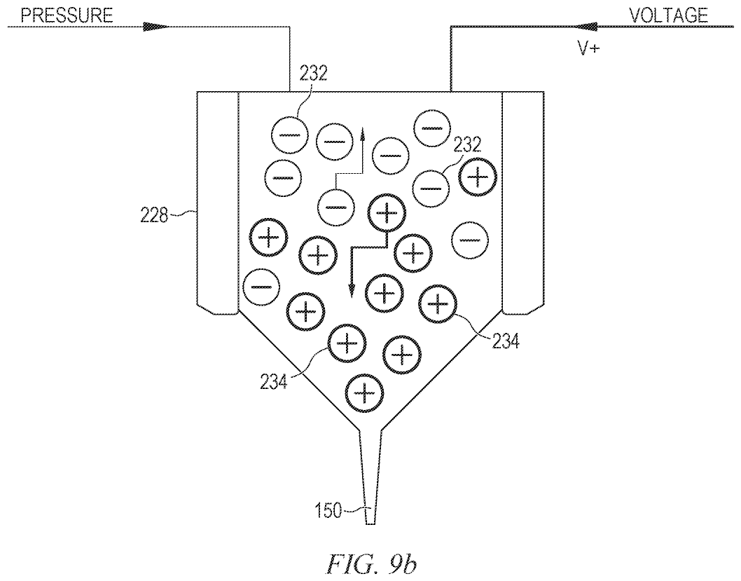

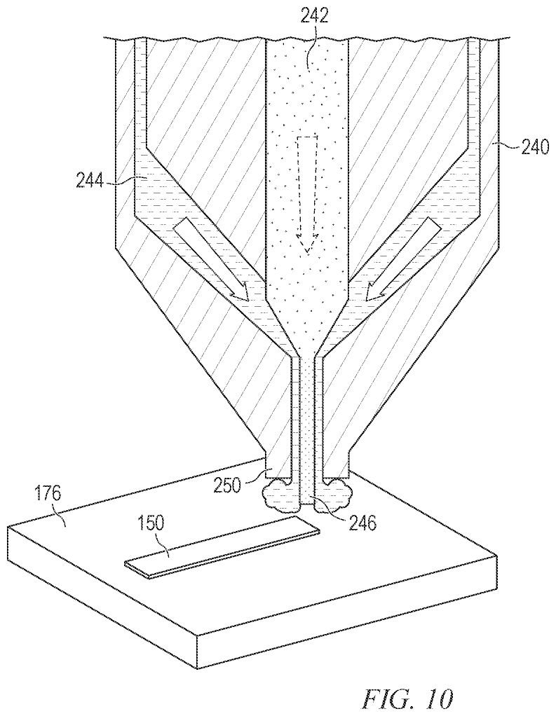

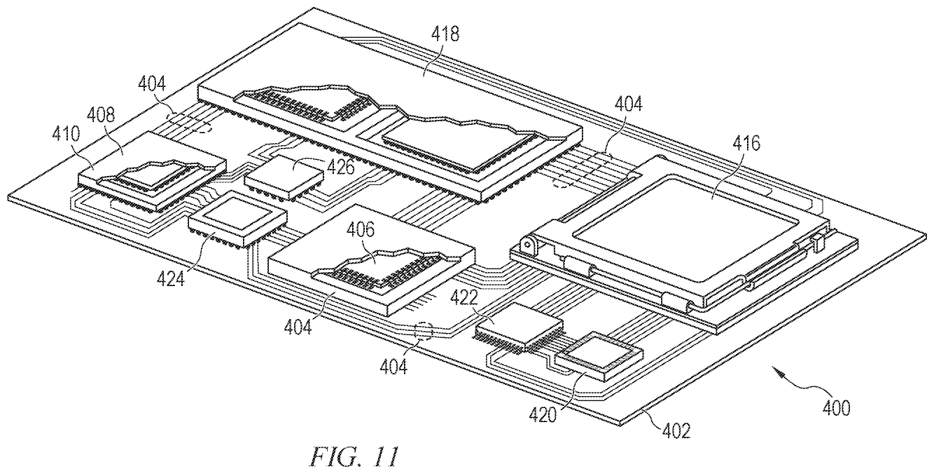

Conductive layer 180c is electrically connected between conductive layer 112d of electrical component 130a and conductive via 144a in electrical connector 140a. Conductive layer 180d is electrically connected between conductive layer 112a of electrical component 130b and conductive via 144b in electrical connector 140a. Conductive layer 180e is electrically connected to conductive layer 112c of electrical component 130b and conductive layer 180f is electrically connected to conductive layer 112d of electrical component 130b. In one embodiment, conductive layers or material 180a-180f, collectively referred to as conductive layer 180, are printed or dispensed onto surfaces 110 and 147 by printer or dispenser 179, as described in FIGS. 9a-9b and 10. Conductive layer 180 follows a similar formation and function as conductive layer 150 in FIGS. 3a-3b and 4a-4c.

In FIG. 6b, conductive layer 180a-180f undergoes an IPL irradiation process using radiation source 181, similar to FIG. 2j.

In FIG. 6c, insulating layer 182 is formed over semiconductor assembly 148 and conductive layer 180. Insulating layer 182 contains one or more layers of SiO₂, Si₃N₄, SiON, Ta₂O₅, Al₂O₃, solder resist, polyimide, BCB, PBO, and other material having similar insulating and structural properties. Insulating layer 182 can be formed using PVD, CVD, printing, lamination, spin coating, spray coating, sintering or thermal oxidation.

In FIG. 6d, a portion of insulating layer 182 is removed using an etching process or LDA with laser 183 to form openings 184 and expose conductive layers or material 180a-180f.

In FIG. 6e, an electrically conductive bump material is deposited into openings 184 over conductive layers 180a-180f using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 180 using a suitable attachment or bonding process. In one embodiment, the bump material is reflowed by heating the material above its melting point to form balls or bumps 186. In one embodiment, bump 186 is formed over a UBM having a wetting layer, barrier layer, and adhesive layer. Bump 186 can also be compression bonded or thermocompression bonded to conductive layer 180. In one embodiment, bump 186 is a copper core bump for durability and maintaining its height. Bump 186 represents one type of interconnect structure that can be formed over conductive layer 180. The interconnect structure can also use bond wires, conductive paste, stud bump, micro bump, or other electrical interconnect.

In FIG. 6f, substrate 120 and bonding layer 129 are removed by CMP, mechanical peel-off, mechanical grinding, thermal bake, UV light, or wet stripping, leaving semiconductor assembly 190.

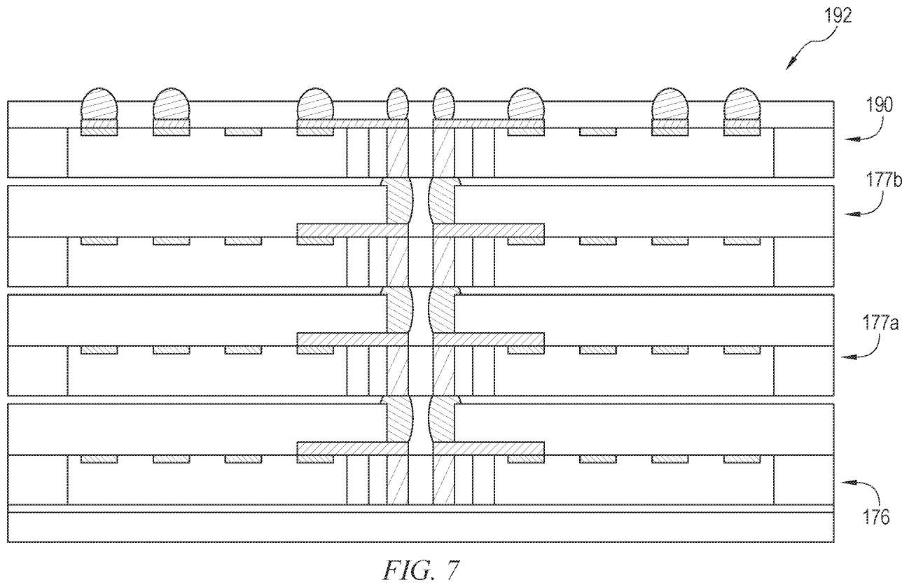

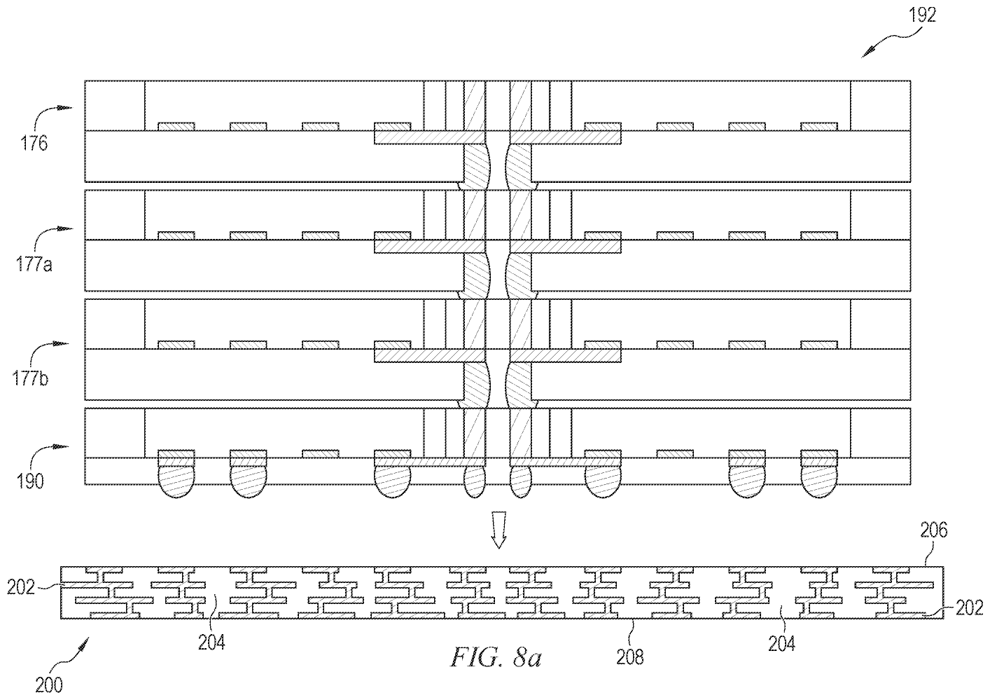

In FIG. 7, semiconductor assembly 190 is disposed over and mounted to semiconductor assembly 177b from FIG. 5c in a manner similar to FIGS. 5a-5b. In particular, the electrical signal conduction path from conductive layer 112d on electrical component 130a in semiconductor assembly 177b is routed through conductive layer 150a in semiconductor assembly 177b, bump 175 in semiconductor assembly 177b, conductive via 144a of electrical connector 140 in semiconductor assembly 190, and conductive layer 180c in semiconductor assembly 190 to conductive layer 112d in electrical components 130a in semiconductor assembly 190. The electrical signal conduction path from conductive layer 112a on electrical component 130b in semiconductor assembly 177b is routed through conductive layer 150b in semiconductor assembly 177b, bump 175 in semiconductor assembly 177b, conductive via 144b of electrical connector 140 in semiconductor assembly 190, and conductive layer 180d in semiconductor assembly 190 to conductive layer 112a in electrical components 130b in semiconductor assembly 190. Electrical components 130a-130b in semiconductor assemblies 176, 177a, and 177b can electrically communicate through conductive layers 150, electrical connectors 140, and conductive layers 180a-180f to electrical components 130a-130b in semiconductor assembly 190, as well as external bumps 186. The combination of semiconductor assemblies 176, 177a, 177b, and 190 constitute semiconductor assembly 192.

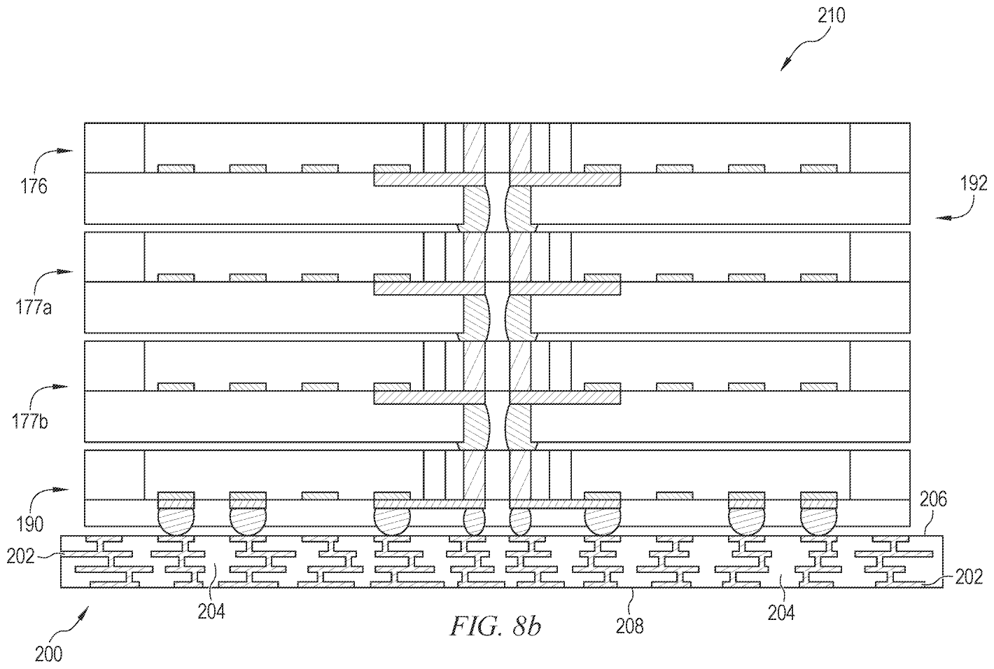

In FIG. 8a, substrate 120 and bonding layer 129 are removed by CMP, mechanical peel-off, mechanical grinding, thermal bake, UV light, or wet stripping from semiconductor assembly 176. A cross-sectional view of multi-layered interconnect substrate 200 is shown including conductive layers 202 and insulating layers 204. Conductive layers 202 can be one or more layers of Al, Cu, Sn, Ni, Au, Ag, or other suitable electrically conductive material. Conductive layers can be formed using PVD, CVD, electrolytic plating, electroless plating process, or other suitable metal deposition process. Conductive layers 202 provides horizontal electrical interconnect across substrate 200 and vertical electrical interconnect between top surface 206 and bottom surface 208 of substrate 200. Portions of conductive layers 202 can be electrically common or electrically isolated depending on the design and function of semiconductor die 104 and other electrical components. Insulating layers 204 contains one or more layers of SiO₂, Si₃N₄, SiON, Ta₂O₅, Al₂O₃, solder resist, polyimide, BCB, PBO, and other material having similar insulating and structural properties. Insulating layers can be formed using PVD, CVD, printing, lamination, spin coating, spray coating, sintering or thermal oxidation. Insulating layers 204 provides isolation between conductive layers 202.

Semiconductor assembly 192 is disposed on surface 206 of interconnect substrate 200 and electrically and mechanically connected to conductive layers 202. Bumps 186 of semiconductor assembly 190 are brought into contact with conductive layer 202 on surface 206 of substrate 200. Semiconductor assembly 192 is electrically and mechanically connected to conductive layer 202 by reflowing bumps 186. FIG. 8b illustrates semiconductor assembly 192 electrically and mechanically connected to conductive layers 202 of substrate 200 and designated as SiP or semiconductor package 210. SiP 210 provides a semiconductor stacking method and structure using electrical connectors and graphene core shells to improve interconnectivity, electrical conductivity, thermal conductivity, and performance, while reducing resistivity. SiP 210, including electrical connector 140 and conductive layers 150 and 180, provides higher density of semiconductor die in a smaller space with extended electrical functionality. In particular, conductive layers 150 and 180 with graphene core shells improves signal transmission and reduces propagation delay. The IPL irradiation performs an anneal in less time than a thermal sintering.

FIGS. 9a-9b and 10 illustrate further detail of dispensers 149 and 179. FIG. 9a shows depositing conductive layer 150 over surface 147 of encapsulant 146 and active surface 110 of electrical component 130, including conductive layer 112, in semiconductor assemblies 176, 177a, 177b, and 190 using EHD jet printing. For example, semiconductor assembly 176 is placed on substrate 220 capable of three dimensional (x, y, z directions) movement to control distribution of conductive material 150 on surfaces 110 and 147. Pneumatic regulator 222 with pressure gauge applies pressure to syringe pump 224 containing conductive material 150. Conical section 226 narrows the ink path to injection nozzle 228, which deposits conductive material 150 on surfaces 110 and 147 in a controlled manner. More specifically, injection nozzle 228 performs jetting by an electric field and pressure between the nozzle and substrate. In FIG. 9b, pressure is applied from pneumatic regulator 222. A voltage source induces an electric field shown as negative charges 232 and positive charges 234. The printed liquid is driven by the electric field to achieve direct pattern, high resolution printing of conductive layer 150.

FIG. 10 shows depositing conductive layer 150 over surface 147 of encapsulant 146 and active surface 110 of electrical component 130 in semiconductor assemblies 176, 177a, 177b, and 190 using aerosol jet printing. Dispenser 240 includes channel 242 for the flow of conductive material 150 and channel 244 for the flow of a gas, such as nitrogen. The conductive material is mixed with the gas and deposits the material from nozzle or head 250 on surfaces 110 and 147 as an aerosol jet. The printed liquid, i.e., conductive layer 150 is dispensed as a jetting of aerosol focused by sheath gas at the end of head 250. The above description in FIGS. 9a-9b and 10 applies to conductive layers or material 150 and 180.

FIG. 11 illustrates electrical device 400 having a chip carrier substrate or PCB 402 with a plurality of semiconductor packages disposed on a surface of PCB 402, including SiP 178 and 210. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 11, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first electrical component;
an electrical connector disposed adjacent to the first electrical component; and
a conductive layer including a graphene core shell formed between the first electrical component and electrical connector.

2. The semiconductor device of claim 1, further including:
a second electrical component disposed adjacent to a side of the electrical connector opposite the first electrical component; and
an encapsulant deposited around the first electrical component, second electrical component, and electrical connector, wherein the conductive layer including the graphene core shell is formed between the second electrical component and electrical connector over the encapsulant.

3. The semiconductor device of claim 1, wherein the graphene core shell includes a copper core or silver core.

4. The semiconductor device of claim 1, wherein the conductive layer includes a plurality of cores covered by graphene and the graphene is interconnected within the conductive layer to form an electrical conduction path.

5. The semiconductor device of claim 1, wherein the conductive layer includes thermoset material or polymer or composite epoxy type matrix and the graphene core shell is embedded within the thermoset material or polymer or composite epoxy type matrix.

6. The semiconductor device of claim 1, further including:
an insulating layer formed over the first electrical component and conductive layer; and
an interconnect structure formed over the conductive layer.

7. A semiconductor device, comprising a plurality of stacked semiconductor assemblies, each semiconductor assembly including:
a first electrical component;
an electrical connector disposed adjacent to the first electrical component; and
a conductive layer including a graphene core shell formed between the first electrical component and electrical connector.

8. The semiconductor device of claim 7, further including:
a second electrical component disposed adjacent to a side of the electrical connector opposite the first electrical component; and
an encapsulant deposited around the first electrical component, second electrical component, and electrical connector, wherein the conductive layer including the graphene core shell is formed between the second electrical component and electrical connector over the encapsulant.

9. The semiconductor device of claim 7, wherein the graphene core shell includes a copper core or silver core.

10. The semiconductor device of claim 7, wherein the conductive layer includes a plurality of cores covered by graphene and the graphene is interconnected within the conductive layer to form an electrical conduction path.

11. The semiconductor device of claim 7, wherein the conductive layer includes thermoset material or polymer or composite epoxy type matrix and the graphene core shell is embedded within the thermoset material or polymer or composite epoxy type matrix.

12. The semiconductor device of claim 7, further including:
an insulating layer formed over the first electrical component and conductive layer; and
an interconnect structure formed over the conductive layer.

13. The semiconductor device of claim 7, further including a pulsed light transmitted onto the conductive layer.

14. A method of making a semiconductor device, comprising:
providing a first electrical component;
disposing an electrical connector adjacent to the first electrical component; and
forming a conductive layer including a graphene core shell between the first electrical component and electrical connector.

15. The method of claim 14, further including:
disposing a second electrical component adjacent to a side of the electrical connector opposite the first electrical component; and
depositing an encapsulant around the first electrical component, second electrical component, and electrical connector, wherein the conductive layer including the graphene core shell is formed between the second electrical component and electrical connector over the encapsulant.

16. The method of claim 14, wherein the graphene core shell includes a copper core or silver core.

17. The method of claim 14, wherein the conductive layer includes a plurality of cores covered by graphene and the graphene is interconnected within the conductive layer to form an electrical conduction path.

18. The method of claim 14, wherein the conductive layer includes thermoset material or polymer or composite epoxy type matrix and the graphene core shell is embedded within the thermoset material or polymer or composite epoxy type matrix.

19. The method of claim 14, further including:
forming an insulating layer over the first electrical component and conductive layer; and
forming an interconnect structure over the conductive layer.

20. A method of making a semiconductor device, comprising a plurality of stacked semiconductor assemblies, each semiconductor assembly including:
providing a first electrical component;
disposing an electrical connector adjacent to the first electrical component; and
forming a conductive layer including a graphene core shell between the first electrical component and electrical connector.

21. The method of claim 20, further including:
disposing a second electrical component disposed adjacent to a side of the electrical connector opposite the first electrical component; and
depositing an encapsulant around the first electrical component, second electrical component, and electrical connector, wherein the conductive layer including the graphene core shell is formed between the second electrical component and electrical connector over the encapsulant.

22. The method of claim 20, wherein the graphene core shell includes a copper core or silver core.

23. The method of claim 20, wherein the conductive layer includes a plurality of cores covered by graphene and the graphene is interconnected within the conductive layer to form an electrical conduction path.

24. The method of claim 20, wherein the conductive layer includes thermoset material or polymer or composite epoxy type matrix and the graphene core shell is embedded within the thermoset material or polymer or composite epoxy type matrix.

25. The method of claim 20, further including:
forming an insulating layer over the first electrical component and conductive layer; and
forming an interconnect structure over the conductive layer.
